(19) United States
(12) Patent Application Publication
(10) Pub. No.: US 2026/0198204 A1
(43) Pub. Date: Jul. 9, 2026

(54) DISPLAY DEVICE

(71) Applicant: Samsung Display Co., LTD., Yongin-si, Gyeonggi-do (KR)

(72) Inventor: Se Dae KI, Yongin-si, Gyeonggi-do (KR)

(21) Appl. No.: 19/288,325

(22) Filed: Aug. 1, 2025

(30) Foreign Application Priority Data
Jan. 3, 2025 (KR) 10-2025-0000899

(51) Int. Cl. H10K 59/80; H05K 5/03; H10K 59/95

(52) U.S. Cl. CPC H10K 59/872; H05K 5/03; H10K 59/95

(57) ABSTRACT

A display device includes a display panel; a flexible circuit board attached to the display panel and outside the display panel; an optical member on an upper surface of the display panel; a cover window including a first portion overlapping the optical member, a second portion not overlapping the optical member, and a third portion not overlapping the display panel and the flexible circuit board; a filler on a surface of the third portion of the cover window facing the display panel; a bracket on a lower surface of the display panel; and a coupling structure on the bracket and around the flexible circuit board. A groove is defined in the third portion of the cover window, the filler is in the groove, and one end of the coupling structure is in the groove of the cover window and is in direct contact with the filler.

This application claims priority to Korean Patent Application No. 10-2025-0000899, filed on Jan. 3, 2025, and all the benefits accruing therefrom under 35 U.S.C. § 119, the content of which in its entirety is herein incorporated by reference.

### BACKGROUND

### 1. Field

The present disclosure relates to a display device.

### 2. Description of the Related Art

A display device provides information to the user by displaying various images on a display screen thereof. In general, the display device includes a screen that displays images and a bezel that does not display images.

As the information society develops, the demand for display devices for displaying images is increasing in various forms, and in terms of design, a display device with a reduced bezel has recently been highlighted. Accordingly, various display device design technologies for reducing the bezel are being developed in the industry.

### SUMMARY

Embodiments of the present disclosure provide a display device with a narrow bezel while having a robust coupling of a cover window and a bracket.

However, embodiments of the present disclosure are not restricted to those set forth herein. The above and other embodiments of the present disclosure will become more apparent to one of ordinary skill in the art to which the present disclosure pertains by referencing the detailed description of the present disclosure given below.

According to an embodiment of the present disclosure, a display device includes a display panel; a flexible circuit board attached to the display panel and positioned outside the display panel; an optical member positioned on an upper surface of the display panel; a cover window including a first portion positioned on the optical member and overlapping the optical member, a second portion which does not overlap the optical member and is positioned outside the first portion, and a third portion which does not overlap the display panel and the flexible circuit board and is positioned outside the second portion; a filler positioned on a surface of the third portion of the cover window facing the display panel; a bracket positioned on a lower surface of the display panel and overlapping the display panel; and a coupling structure positioned on a surface of the bracket opposite to another surface of the bracket facing the display panel and further positioned around the flexible circuit board, where the a groove recessed inwardly from a surface of the cover window facing the display panel is defined in the third portion of the cover window, the filler is positioned on inner side surfaces of the cover window defining the groove, and one end of the coupling structure is positioned in the groove of the cover window and is in direct contact with the filler.

In an embodiment, a direction of the cover window toward the display panel is defined as a first direction, and a direction intersecting the first direction is defined as a second direction, and a width in the second direction of a surface facing the display panel among the inner side surfaces of the cover window defining the groove and a width of a boundary between the inner side surfaces of the cover window defining the groove and an outer side surface of the cover window in the second direction may be different from each other.

In an embodiment, the width in the second direction of the surface facing the display panel among the inner side surfaces of the cover window defining the groove may be greater than the width of the boundary between the inner side surfaces of the cover window defining the groove and the outer side surface of the cover window in the second direction.

In an embodiment, the display device may further include a light blocking layer positioned on surfaces of the second portion and the third portion of the cover window facing the display panel, and further positioned on the inner side surfaces of the cover window defining the groove, where the light blocking layer may be positioned between the cover window and the filler, and the coupling structure may not be in direct contact with the light blocking layer.

In an embodiment, the filler may overlap the groove of the cover window and may be further positioned outside the cover window.

In an embodiment, the display device may further include a light blocking layer positioned on surfaces of the second portion and the third portion of the cover window facing the display panel, and further positioned on the inner side surfaces of the cover window defining the groove, where the light blocking layer may be positioned between the cover window and the filler, and the coupling structure may be in direct contact with the light blocking layer.

In an embodiment, a direction of the cover window toward the display panel is defined as a first direction, and a direction intersecting the first direction is defined as a second direction, and a width in the second direction of a surface facing the display panel among the inner side surfaces of the cover window defining the groove and a width of a boundary between the inner side surfaces of the cover window defining the groove and an outer side surface of the cover window in the second direction may be equal to each other.

In an embodiment, the groove may penetrate through the cover window, and the display device may further include a light blocking layer includes a first light blocking layer positioned on surfaces of the second portion and the third portion of the cover window facing the display panel, and a second light blocking layer positioned on a surface of the cover window opposite to the surfaces of the second portion and the third portion of the cover window facing the display panel and overlapping the groove of the cover window.

In an embodiment, the bracket and the coupling structure may be integrally formed as a single unitary indivisible part.

In an embodiment, the coupling structure may include a first coupling structure and a second coupling structure positioned on one side of the bracket overlapping the flexible circuit board.

In an embodiment, the coupling structure may further include a third coupling structure and a fourth coupling structure positioned on another side of the bracket opposite to the one side of the bracket.

In an embodiment, the inner side surfaces of the cover window defining the groove may include a curved surface.

In an embodiment, the display device may further include a light blocking layer positioned on surfaces of the second portion and the third portion of the cover window facing the display panel, and further positioned on the inner side surfaces of the cover window defining the groove, where the light blocking layer may be positioned between the cover window and the filler, and the coupling structure may not be in direct contact with the light blocking layer.

According to an embodiment of the present disclosure, a display device includes a display panel; a flexible circuit board attached to the display panel and positioned on the outside of the display panel; an optical member positioned on an upper surface of the display panel; a cover window including a first portion positioned on the optical member and overlapping the optical member, a second portion which does not overlap the optical member and is positioned outside the first portion, and a third portion which does not overlap the display panel and the flexible circuit board and is positioned outside the second portion; a filler positioned between a surface of the cover window facing the display panel and another surface of the cover window opposite to the surface facing the display panel; a bracket positioned on a lower surface of the display panel and overlapping the display panel; and a coupling structure positioned on a surface of the bracket opposite to another surface of the bracket facing the display panel and further positioned around the flexible circuit board, where a groove recessed inwardly from a side surface of the cover window is defined in the third portion of the cover window, the filler is positioned in inner side surfaces of the cover window defining the groove, and one end of the coupling structure is positioned in the groove of the cover window and is in direct contact with the filler.

In an embodiment, the display device may further include a light blocking layer includes a first light blocking layer positioned on surfaces of the second portion and the third portion of the cover window facing the display panel, and a second light blocking layer positioned on a surface of the cover window opposite to the surfaces of the second portion and the third portion of the cover window facing the display panel and overlapping the groove of the cover window.

In an embodiment, the coupling structure may not be in direct contact with the cover window.

In an embodiment, the groove may extend to the second portion of the cover window.

In an embodiment, the coupling structure may include a first coupling structure and a second coupling structure positioned on one side of the bracket overlapping the flexible circuit board.

In an embodiment, the coupling structure may further include a third coupling structure and a fourth coupling structure positioned on another side of the bracket opposite to the one side of the bracket.

According to an embodiment of the present disclosure, an electronic device including a display device, includes a display panel; a flexible circuit board attached to the display panel and positioned on the outside of the display panel; an optical member positioned on an upper surface of the display panel; a cover window including a first portion positioned on the optical member and overlapping the optical member, a second portion which does not overlap the optical member and is positioned outside the first portion, and a third portion which does not overlap the display panel and the flexible circuit board and is positioned outside the second portion; a filler positioned on a surface of the third portion of the cover window facing the display panel; a bracket positioned on a lower surface of the display panel and overlapping the display panel; and a coupling structure positioned on a surface of the bracket opposite to another surface of the bracket facing the display panel and further positioned around the flexible circuit board, where a groove recessed inwardly from a surface of the cover window facing the display panel is defined in the third portion of the cover window, the filler is positioned in an inner side of the cover window defining the groove, and one end of the coupling structure is positioned in the groove of the cover window and is in direct contact with the filler.

According to some embodiments, a display device having improved display quality and improved reliability may be provided.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other features of embodiments of the present disclosure will become more apparent by describing in detail embodiments thereof with reference to the accompanying drawings, in which:

FIG. 1 is an exploded perspective view of a display device according to an embodiment;

FIG. 2 is a bottom view of the display device according to an embodiment;

FIG. 3 is a cross-sectional view of the display device of FIG. 2 taken along line X1-X1′;

FIG. 4 is an enlarged cross-sectional view of a portion B1 of FIG. 3;

FIGS. 5 to 8 are cross-sectional views illustrating other embodiments of the display device, which are enlarged views of portion B1 of FIG. 3;

FIGS. 9 to 12 are cross-sectional views of splay devices according to other embodiments, showing a cross-section taken along line X1-X1′ of FIG. 2;

FIGS. 13 and 15 are bottom views of display devices according to still other embodiments;

FIG. 16 is a bottom view of a display device according to still another embodiment;

FIG. 17 is a cross-sectional view of the display device of FIG. 16 taken along line X3-X3′;

FIG. 18 is an enlarged cross-sectional view of portion B3 of FIG. 17;

FIGS. 19 and 20 are cross-sectional views of display devices according to still other embodiments, showing a cross-section taken along line X3-X3′ of FIG. 16;

FIG. 21 is a bottom view of a display device according to still another embodiment;

FIG. 22 is a block diagram of an electronic device according to an embodiment; and

FIG. 23 illustrates schematic diagrams of electronic devices according to various embodiments.

### DETAILED DESCRIPTION

The invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art. Like reference numerals refer to like elements throughout.

It will also be understood that when a layer is referred to as being “on” another layer or substrate, it can be directly on the other layer or substrate, or intervening layers may also be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Each of the features of the various embodiments of the present disclosure may be combined or combined with each other, in part or in whole, and technically various interlocking and driving are possible. Each embodiment may be implemented independently of each other or may be implemented together in an association.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described with reference to the accompanying drawings.

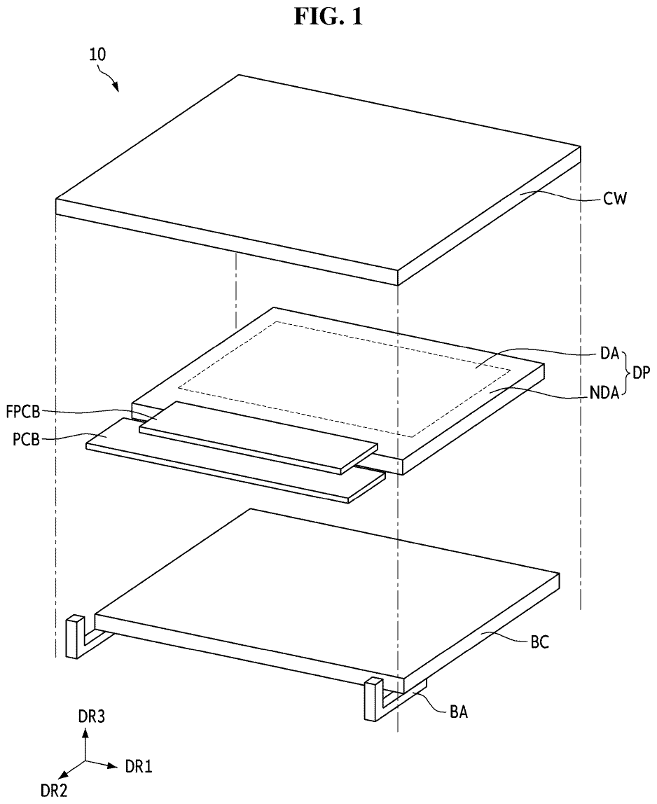

FIG. 1 is an exploded perspective view of a display device according to an embodiment.

A display device 10 according to an embodiment is a device that displays a moving image or still image and may be used as a display screen for various products.

The display device 10 may be a light emitting display device such as an organic light emitting display device using an organic light emitting diode (LED), a quantum dot light emitting display device including a quantum dot light emitting layer, an inorganic light emitting display device including an inorganic semiconductor, or a micro light emitting display device using a micro light emitting diode (LED). Hereinafter, for convenience of description, embodiments where the display device 10 is the organic light emitting display device will be mainly described, but the present disclosure is not limited thereto.

In the present disclosure, a first direction DR1 may be a direction parallel to a short side of the display device 10 in a plan view, for example, a vertical direction of the display device 10. A second direction DR2 may be a direction parallel to a long side of the display device 10 in a plan view, for example, a horizontal or longitudinal direction of the display device 10. A third direction DR3 may be a thickness direction of the display device 10. The display device 10 may have a rectangular shape in a plan view.

Referring to FIG. 1, the display device 10 according to an embodiment may include a cover window CW, a display panel DP, a bracket BC, and a coupling structure BA.

The cover window CW may be disposed above the display panel DP to cover an upper surface of the display panel DP. The cover window CW may serve to protect the upper surface of the display panel DP.

The display panel DP may be a light emitting display panel including a light emitting element. The display panel DP may be disposed under the cover window CW. The display panel DP may include a display area DA and a non-display area NDA positioned around the display area DA. The display area DA, which is an area that displays an image, may occupy most of the area of the display panel DP. The non-display area NDA of the display panel DP, which is an area that does not display the image, may constitute a bezel of the display device 10. The non-display area NDA may include an area protruding in the second direction DR2 from one side of the display area DA. A flexible printed circuit board (FPCB) may be disposed in the protruding area of the non-display area NDA of the display panel DP. FIG. 1 shows an embodiment of the display device 10 in a state where the flexible printed circuit board (FPCB) disposed in the non-display area NDA of the display panel DP is unfolded, but the flexible printed circuit board (FPCB) may be bent in another state. In addition, a rigid printed circuit board (PCB) may be disposed at an end opposite to the end of the flexible printed circuit board (FPCB) disposed on the display panel DP.

The bracket BC may be disposed under the display panel DP. The bracket BC may support the display panel DP of the display device 10.

The coupling structure BA may be disposed under the bracket BC. The coupling structure BA may be coupled to the cover window CW by including a portion positioned further outside the bracket BC and extending in the third direction DR3.

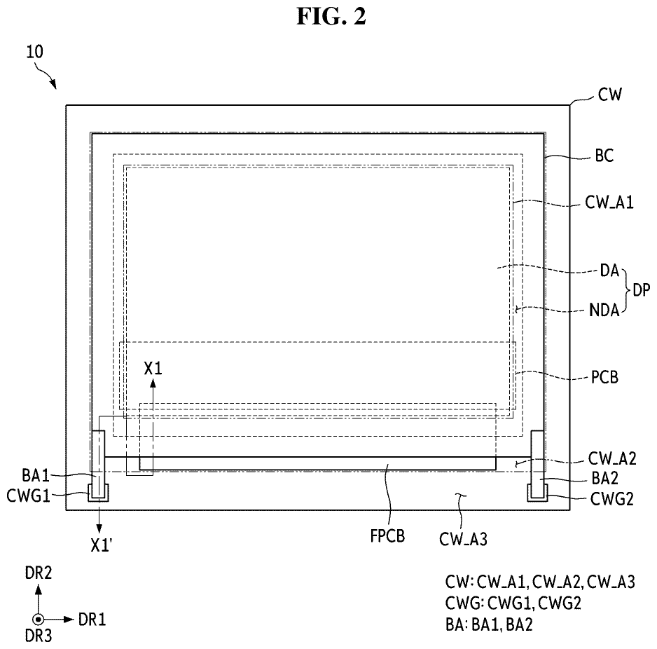

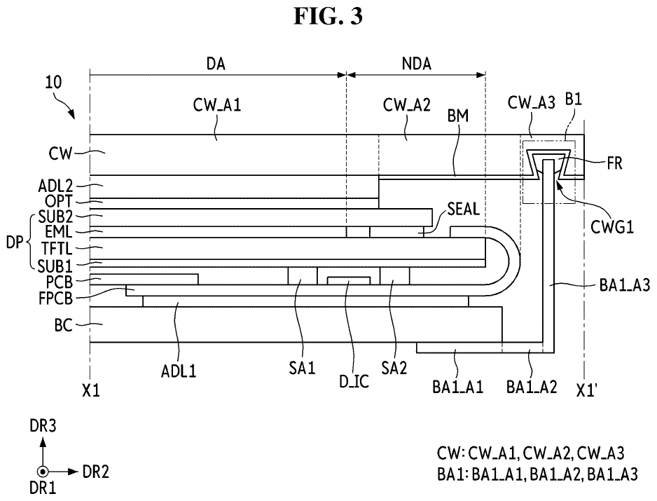

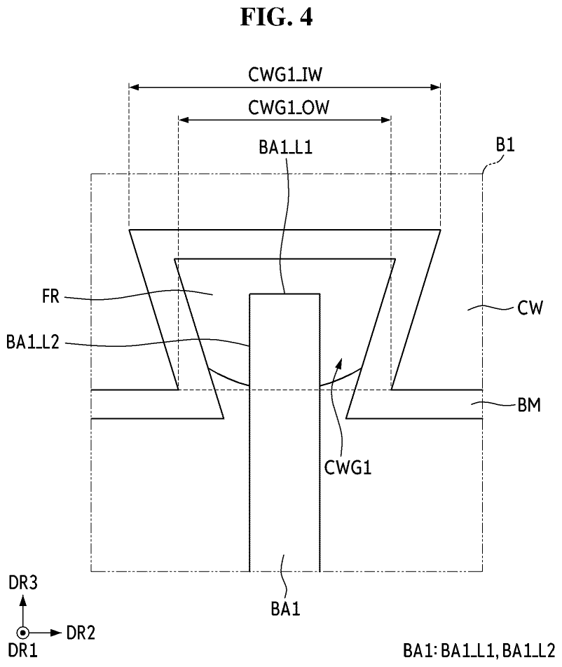

FIG. 2 is a bottom view of the display device according to an embodiment. FIG. 3 is a cross-sectional view of the display device of FIG. 2 taken along line X1-X1′. FIG. 4 is an enlarged cross-sectional view of a portion B1 of FIG. 3.

Referring to FIGS. 2, 3, and 4, in an embodiment, the display device 10 may include a display panel DP, a flexible printed circuit board (FPCB) positioned on the periphery of the display panel DP and bent to be positioned under the display panel DP, an optical member OPT positioned on the display panel DP, a cover window CW positioned on the optical member OPT, a bracket BC positioned under the display panel DP and the flexible printed circuit board (FPCB), and a coupling structure BA positioned under the bracket BC. The display device 10 may further include a first adhesive layer ADL1 positioned between the flexible printed circuit board (FPCB) and the bracket BC and a second adhesive layer ADL2 positioned between the optical member OPT and the cover window CW.

The display panel DP may include a first substrate SUB1, a thin film transistor layer TFTL positioned on the first substrate SUB1, a light emitting layer EML and a sealing member SEAL positioned on the thin film transistor layer TFTL, and a second substrate SUB2 positioned on the light emitting layer EML and the sealing member SEAL. In some embodiments, the display panel DP may further include a touch sensing layer (not shown) positioned on the second substrate SUB2. In an embodiment where the display panel DP further includes the touch sensing layer, another flexible printed circuit board disposed on the periphery of the display panel DP and bent to be positioned under the display panel DP may be further positioned.

The first substrate SUB1 may be a base member that supports layers of the display panel DP. In some embodiments, the first substrate SUB1 may be a rigid substrate and may include a glass material or a metal material. Alternatively, in some embodiments, the substrate SUB may be a flexible substrate capable of being bent, folded, rolled, etc., and may include a polymer resin such as polyimide (PI), but is not limited thereto.

The thin film transistor layer TFTL may be positioned on the first substrate SUB1. The thin film transistor layer TFTL may include a plurality of thin film transistors constituting a pixel circuit of pixels. The thin film transistor layer TFTL may be positioned in the display area DA and the non-display area NDA.

The light emitting layer EML may be positioned on the thin film transistor layer TFTL. The light emitting layer EML may be positioned in the display area DA and the non-display area NDA. The light emitting layer EML may include a plurality of light emitting elements including an anode, a cathode, and a light emitting layer to emit light, and a pixel defining film that defines the pixels. The plurality of light emitting elements of the light emitting layer EML may be positioned in the display area DA. The pixel defining film of the light emitting layer EML may be positioned in the display area DA and may be further positioned in the non-display area NDA.

The sealing member SEAL may be positioned on the thin film transistor layer TFTL. The sealing member SEAL may be positioned in the non-display area NDA. The sealing member SEAL may overlap the non-display area NDA in the third direction DR3. The sealing member SEAL may be disposed to surround the light emitting layer EML in the non-display area NDA. The sealing member SEAL may protect a side surface of the light emitting layer EML. The sealing member SEAL may include an inorganic material for preventing oxygen or moisture from permeating into the light emitting layer EML.

The second substrate SUB2 may be positioned on the light emitting layer EML and the sealing member SEAL. The second substrate SUB2 may be positioned in the display area DA and the non-display area NDA. The second substrate SUB2 may overlap the display area DA and the non-display area NDA in the third direction DR3. The second substrate SUB2 may cover an upper surface of the light emitting layer EML in the display area DA and the non-display area NDA. The second substrate SUB2 may be positioned on the sealing member SEAL in the non-display area NDA. The second substrate SUB2 may be an encapsulation layer for protecting the light emitting layer EML. The second substrate SUB2 may include at least one inorganic film to effectively prevent oxygen or moisture from permeating into the light emitting layer EML. In some embodiments, the second substrate SUB2 may be a rigid substrate and may include a glass material.

The flexible printed circuit board (FPCB) may be disposed on one edge of the display panel DP and may be bent to be positioned under the display panel DP. In an embodiment, the flexible printed circuit board (FPCB) is bent, such that the flexible printed circuit board (FPCB) may overlap the display area DA of the display panel DP in the thickness direction DR3 of the display panel DP. In such an embodiment, one side of the flexible printed circuit board (FPCB) may be disposed on one edge of the thin film transistor layer TFTL of the display panel DP in the non-display area NDA. One side of the flexible printed circuit board (FPCB) may be disposed outside the sealing member SEAL not to overlap the light emitting layer EML and the sealing member SEAL positioned on the thin film transistor layer TFTL. The other side opposite to one side of the flexible printed circuit board (FPCB) may be bent on the outside of the display panel DP and positioned on the lower surface of the first substrate SUB1 of the display panel DP. The flexible printed circuit board (FPCB) may be fixed or attached to the lower surface of the first substrate of the display panel DP by support members SA1 and SA2 under the display panel. A display driving circuit D_IC may be disposed on the flexible printed circuit board (FPCB). In addition, a rigid printed circuit board (PCB) may be disposed on the other edge of the flexible printed circuit board (FPCB).

The optical member OPT may be positioned on the second substrate SUB2 of the display panel DP. The optical member OPT may be positioned in the display area DA and may be further positioned in the non-display area NDA. The optical member OPT may prevent degradation in visibility caused by reflection of external light. In some embodiments, the optical member OPT may be replaced with another anti-reflection layer, such as a color filter layer including a plurality of color filters.

The cover window CW may be disposed on the optical member OPT. The cover window CW may include a first portion CW_A1 overlapping the optical member OPT of the display panel DP, a second portion CW_A2 that does not overlap the optical member OPT of the display panel DP and is positioned outside the first portion CW_A1, and a third portion CW_A3 that does not overlap the flexible printed circuit board (FPCB) and is positioned outside the second portion CW_A2. The third portion CW_A3 of the cover window may include (or define) a plurality of grooves CWG recessed inwardly from a surface of the cover window CW facing the display panel DP. The third portion CW_A3 of the cover window may include (or define) a first groove CWG1 and a second groove CWG2 each positioned at an outer edge of the cover window CW in the first direction DR1. In the disclosure, a width in the second direction DR2 of a surface facing the display panel DP among the inner side surfaces of the cover window CW defining the first groove CWG1 is referred to as a first width CWG1_IW of the first groove, and a width in the second direction DR2 of a boundary between the inner side of the cover window CW defining the first groove CWG1 and the outer side of the cover window CW is referred to as a second width CWG1_OW of the first groove. The first width CWG1_IW of the first groove and the second width CWG1_OW of the first groove may be different from each other. In some embodiments, the first width CWG1_IW of the first groove may be greater than the second width CWG1_OW of the first groove. Alternatively, in some embodiments, the first width CWG1_IW of the first groove may be smaller than the second width CWG1_OW of the first groove. Alternatively, in some embodiments, the first width CWG1_IW of the first groove and the second width CWG1_OW of the first groove may be equal to each other.

A light blocking layer BM may be positioned on the surface of the cover window CW facing the display panel DP. The light blocking layer BM may be positioned on the second portion CW_A2 and the third portion CW_A3 of the cover window. The light blocking layer BM may be further positioned on the inner side surface of the cover window CW defining the first groove CWG1 in the third portion CW_A3 of the cover window. The light blocking layer BM may effectively prevent the non-display area NDA of the display panel DP, the flexible printed circuit board (FPCB), and the coupling structure BA coupled to the cover window CW from being visible to the user in the third direction DR3. The light blocking layer BM may constitute a bezel of the display device 10.

A filler FR may be positioned on a surface of the third portion CW_A3 of the cover window facing the display panel DP. The filler FR may be positioned on the inner side (or inner surface) of the cover window CW defining the first groove CWG1 in the third portion CW_A3 of the cover window. The filler FR may fill the first groove CWG1 of the cover window defined in the third portion CW_A3. The filler FR may be positioned on the light blocking layer BM in the third portion CW_A3 of the cover window. The filler FR may include a curable organic material. In some embodiments, the filler FR may include a heat or light curable resin.

The bracket BC may be positioned under the display panel DP and the flexible printed circuit board (FPCB), and may overlap the display panel DP. The bracket BC may support the display panel DP and the flexible printed circuit board (FPCB), by being positioned under the display panel DP and the flexible printed circuit board (FPCB). The bracket BC may include plastic, metal, or a combination of plastic and metal.

The coupling structure BA may be disposed under the bracket BC. The coupling structure BA may include a first coupling structure BA1 and a second coupling structure BA2, each of which is positioned at an outermost edge of the bracket BC extending in the first direction DR1. The first coupling structure BA1 may include a first portion BA_A1 overlapping the bracket BC in the third direction DR3, a second portion BA1_A2 that does not overlap the bracket BC in the third direction DR3 and is positioned more externally (or outwardly) than the first portion BA1_A1, and a third portion BA1_A3 that does not overlap the display panel DP and the flexible printed circuit board FPCB in the third direction DR3 and is positioned more externally than the second portion BA1_A2. The third portion BA1_A3 of the first coupling structure may be positioned around the flexible printed circuit board (FPCB), extend in a direction toward the cover window CW, and be positioned in the first groove CWG1 of the cover window CW. The third portion BA1_A3 of the first coupling structure may be in direct contact with the filler FR in the first groove CWG1 of the cover window CW. The third portion BA1_A3 of the first coupling structure may be in direct contact with the filler FR in the first groove CWG1 of the cover window CW, and a coupling force between the first coupling structure BA1 and the cover window CW may be formed or provided by the filler FR. In an embodiment, the first width CWG_OW of the first groove is greater than the second width CWG_IW of the first groove, such that the coupling force between the first coupling structure BA1 and the cover window CW may be improved by the filler FR filled in the first groove CWG1 of the cover window CW. As the coupling force between the first coupling structure BA1 and the cover window CW is improved by the filler FR, the cover window CW and the bracket BC may be firmly coupled by the first coupling structure BA1. As the first coupling structure is coupled to the cover window CW, the first coupling structure BA1 may distribute the load applied from the cover window CW to the display panel DP. As the first coupling structure BA1 distributes the load applied from the cover window CW to the display panel DP, the load applied from the cover window CW to the display panel DP may be reduced, thereby reducing the risk of the sealing member SEAL of the display panel DP being peeled off. Therefore, reliability of the display device 10 may be improved. In such an embodiment, since the cover window CW and the bracket BC are coupled by the coupling structure BA in the third portion CW_A3 of the cover window, the display device 10 may have a narrow bezel. Therefore, the display quality of the display device 10 may be improved.

The coupling structure BA may include plastic, metal, or a combination of plastic and metal. The coupling structure BA may be coupled to the bracket BC in various forms. In some embodiments, the coupling structure BA may be fixed to the lower surface of the bracket BC by a fixing member, such as a screw, under the bracket BC. Alternatively, in some embodiments, the coupling structure BA and the bracket BC may be integrally formed as a single unitary indivisible part. The coupling structure BA and the bracket BC may include or be formed of a same material as each other.

Referring to FIG. 4, the first coupling structure BA1 may include a first surface BA1_L1 facing the cover window and a second surface BA1_L2 intersecting the first surface BA1_L1 facing the cover window. The first surface BA1_L1 and the second surface BA1_L2 of the first coupling structure may not be in direct contact with the light blocking layer BM.

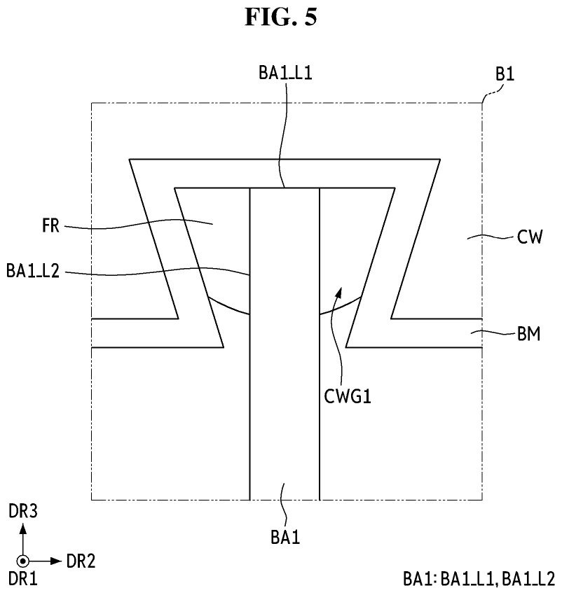

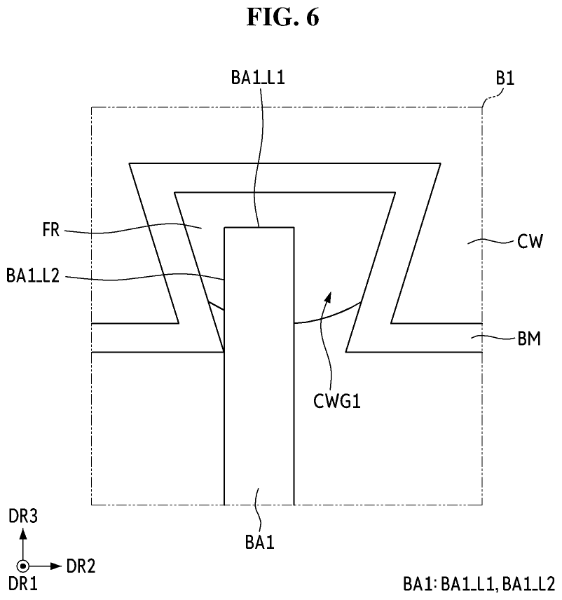

FIGS. 5 to 8 are cross-sectional views illustrating other embodiments of the display device, which are enlarged views of portion B1 of FIG. 3. Hereinafter, for convenience of description, the differences from embodiments described above will be mainly described and any repetitive detailed descriptions of the same or like elements as those described above will be omitted.

Referring to FIG. 5, in another embodiment, the first surface BA1_L1 of the first coupling structure may be in direct contact with the light blocking layer BM, and the second surface BA1_L2 of the first coupling structure may not be in direct contact with the light blocking layer BM.

Referring to FIG. 6, in another embodiment, the first surface BA1_L1 of the first coupling structure may not be in direct contact with the light blocking layer BM, and the second surface BA1_L2 of the first coupling structure may be in direct contact with the light blocking layer BM.

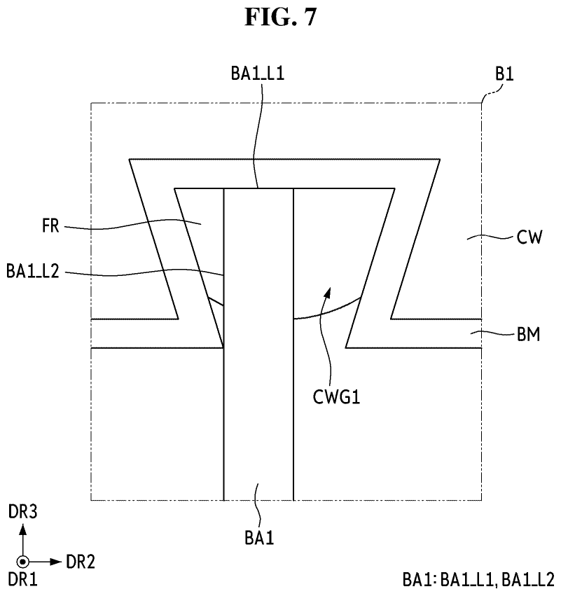

Referring to FIG. 7, in another embodiment, the first surface BA1_L1 and the second surface BA1_L2 of the first coupling structure may be in direct contact with the light blocking layer BM.

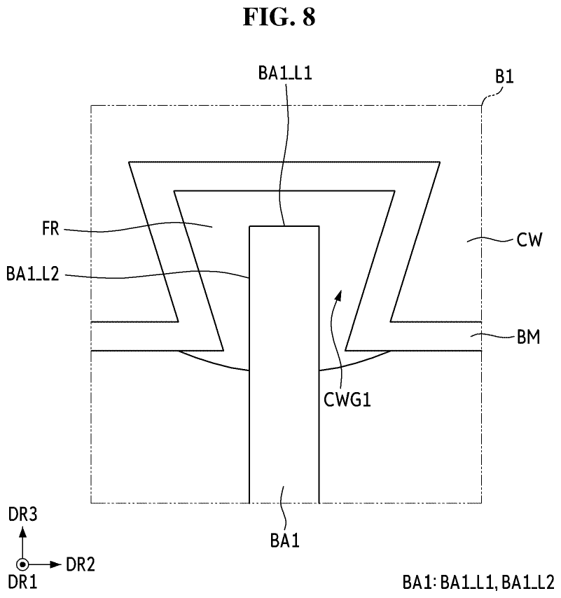

Referring to FIG. 8, in another embodiment, the filler FR may overlap the first groove CWG1 of the cover window CW in the third direction DR3 and may be further positioned outside the first groove CWG1 of the cover window CW.

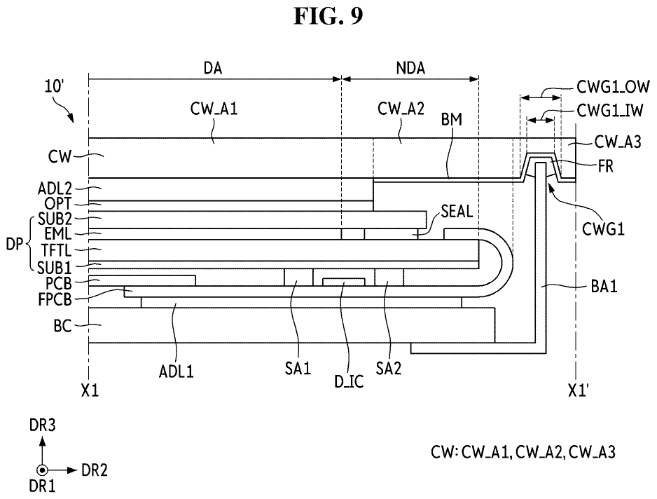

FIGS. 9 to 12 are cross-sectional views of display devices according to other embodiments, showing a cross-section taken along line X1-X1′ of FIG. 2. Hereinafter, for convenience of description, the differences from embodiments described above will be mainly described and any repetitive detailed descriptions of the same or like elements as those described above will be omitted.

Referring to FIG. 9, in another embodiment, the first width CWG1_IW of the first groove may be smaller than the second width CWG1_OW of the first groove.

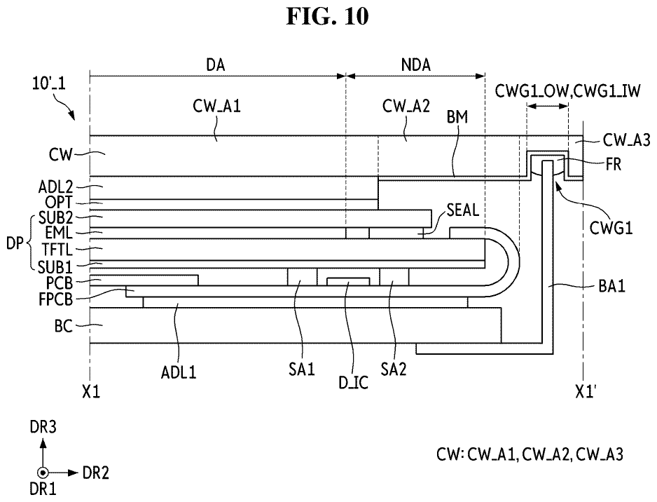

Referring to FIG. 10, in another embodiment, the first width CWG1_IW of the first groove and the second width CWG1_OW of the first groove may be equal to each other.

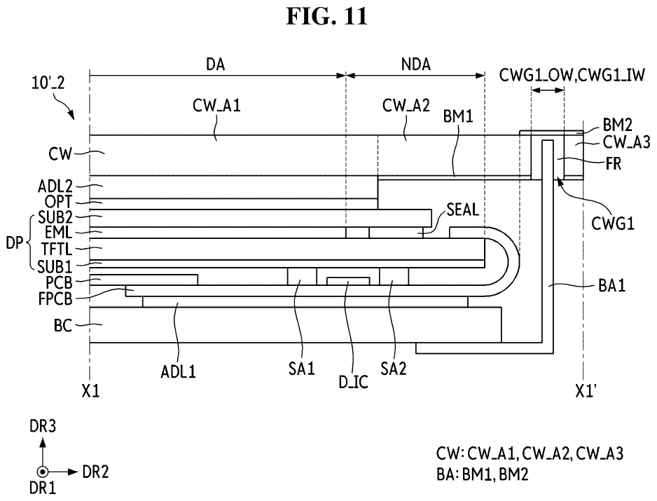

Referring to FIG. 11, in another embodiment, the first groove CWG1 may penetrate through the cover window CW. In such an embodiment where the first groove CWG1 penetrates through the cover window CW, the light blocking layer BM may include a first light blocking layer BM1 and a second light blocking layer BM2. The first light blocking layer BM1 may be positioned on a surface of the second portion CW_A2 and the third portion CW_A3 of the cover window facing the display panel DP, and the second light blocking layer BM2 may be positioned on a surface of the cover window opposite to a surface of the third portion CW_A3 of the cover window facing the display panel DP and may overlap the first groove CWG1 in the third direction DR3.

FIG. 11 illustrates an embodiment where the first width CWG1_IW of the first groove and the second width CWG1_OW of the first groove are equal to each other, but in some other embodiments, the first width CWG1_IW of the first groove and the second width CWG1_OW of the first groove may be different from each other. In an embodiment, for example, the first width CWG1_IW of the first groove may be greater than the second width CWG1_OW of the first groove. Alternatively, in some embodiments, the first width CWG1_IW of the first groove may be smaller than the second width CWG1_OW of the first groove.

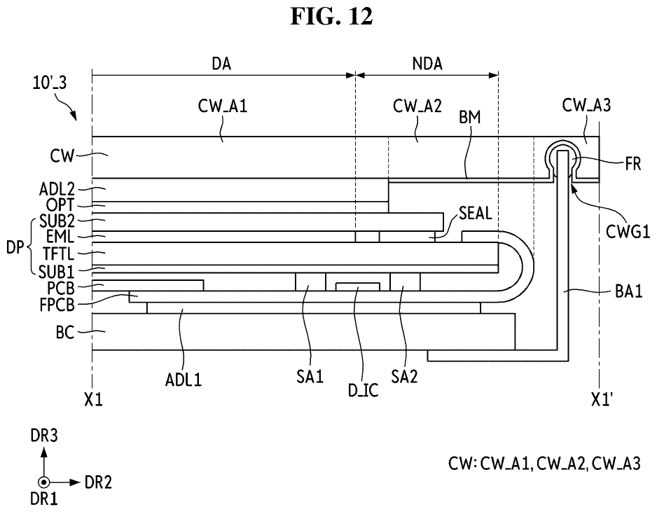

Referring to FIG. 12, in another embodiment, the inner side surface of the cover window CW defining the first groove CWG1 may include a curved surface. As the inner side surface of the cover window CW defining the first groove CWG1 includes the curved surface, a surface area of the inner side surface of the cover window CW defining the first groove CWG1 is increased, such that pressure transmitted from the outside to the cover window CW may be reduced. In such an embodiment, as the surface area of the inner side surface of the cover window CW defining the first groove CWG1 is increased, a surface area of the filler FR filling the first groove CWG1 of the cover window CW is also increased, such that the coupling force between the cover window CW and the first coupling structure BA1 may be further improved by the filler FR. Therefore, the coupling force between the cover window CW and the bracket BC may be further improved by the first coupling structure BA1. Therefore, the reliability of the display device 10 may be further improved.

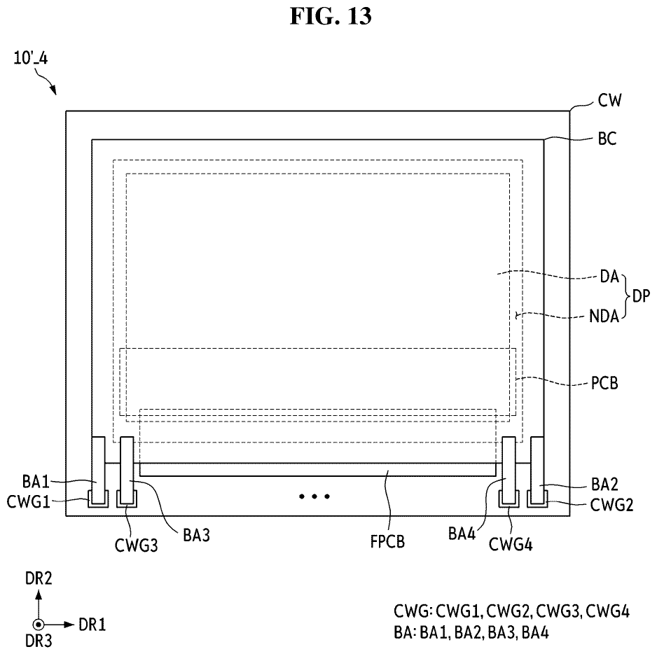

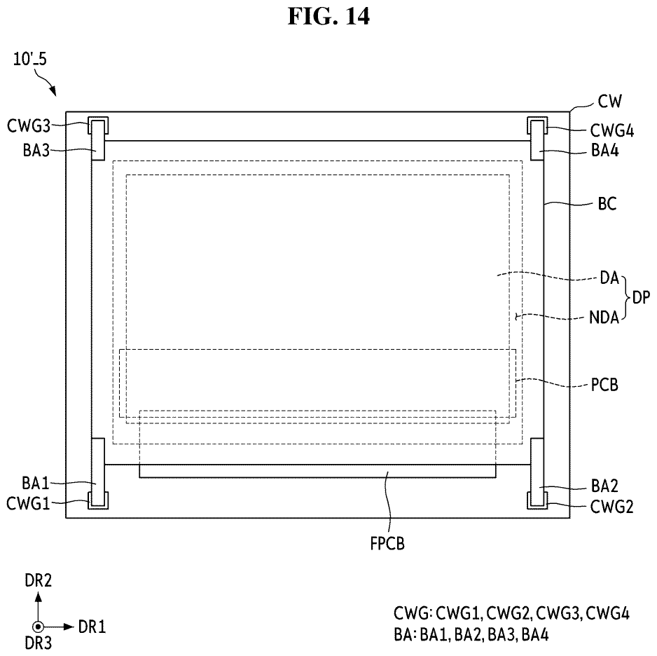

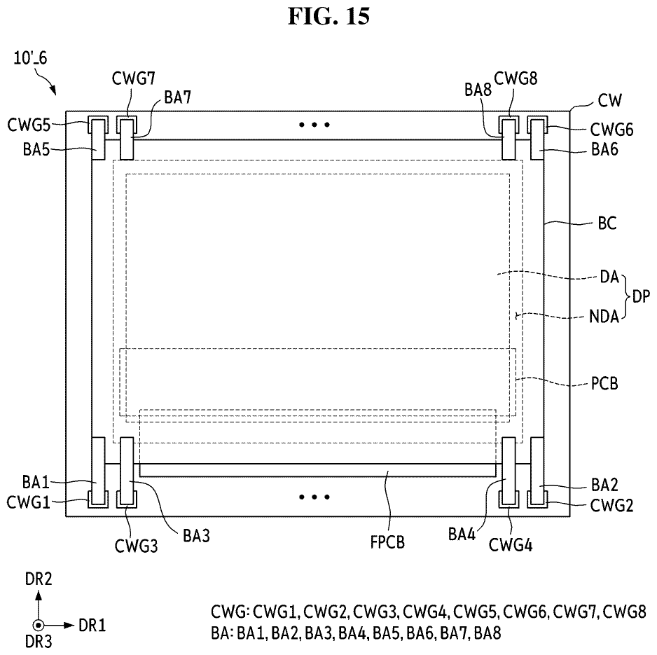

FIGS. 13 and 15 are bottom views of display devices according to still other embodiments. Hereinafter, for convenience of description, the differences from embodiments described above will be mainly described and any repetitive detailed descriptions of the same or like elements as those described above will be omitted.

Referring to FIG. 13, in another embodiment, the coupling structure BA may further include a third coupling structure BA3 and a fourth coupling structure BA4 respectively disposed on the inner sides of the first coupling structure BA1 and the second coupling structure BA2 in the first direction (DR1). In some embodiments, a plurality of coupling structures BA may be further disposed in the inner sides of the third coupling structure BA3 and the fourth coupling structure BA4. In such an embodiment, the display device further includes the plurality of coupling structures BA, such that the coupling force between the cover window CW and the bracket BC may be further improved by the coupling structures BA. Therefore, the reliability of the display device may be further improved.

Referring to FIG. 14, in another embodiment, the coupling structure BA may further include a third coupling structure BA3 and a fourth coupling structure BA4 disposed on an opposing side opposite to one side on which the first coupling structure BA1 and the second coupling structure BA2 of the bracket BC are positioned. In such an embodiment, the coupling structure BA of the display device further includes the third coupling structure BA3 and the fourth coupling structure BA4 disposed on the opposing side opposite to one side on which the first coupling structure BA1 and the second coupling structure BA2 of the bracket BC are positioned, such that the coupling force between the cover window CW and the bracket BC may be further improved by the coupling structure BA. Therefore, the reliability of the display device may be further improved.

Referring to FIG. 15, in another embodiment, the coupling structure BA may further include fifth to eighth coupling structures BA5, BA6, BA7, and BA8 disposed to correspond to the first to fourth coupling structures BA1, BA2, BA3, and BA4 on the other side opposite to one side on which the first to fourth coupling structures BA1, BA2, BA3, and BA4 of the bracket BC are positioned. In such an embodiment, the coupling structure BA of the display device further includes the fifth to eighth coupling structures BA5, BA6, BA7, and BA8 disposed to correspond to the first to fourth coupling structures BA1, BA2, BA3, and BA4 on the other side opposite to one side on which the first to fourth coupling structures BA1, BA2, BA3, and BA4 of the bracket BC are positioned, such that the coupling force between the cover window CW and the bracket BC may be further improved by the coupling structure BA. In some embodiments, a plurality of coupling structures BA may be further disposed in the inner sides of the third coupling structure BA3 and the fourth coupling structure BA4, and the seventh coupling structure BA7 and the eighth coupling structure BA8.

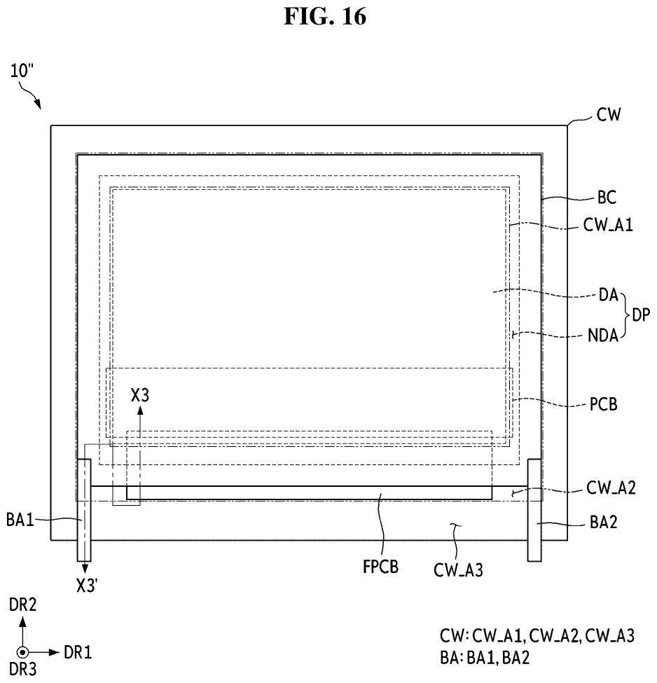

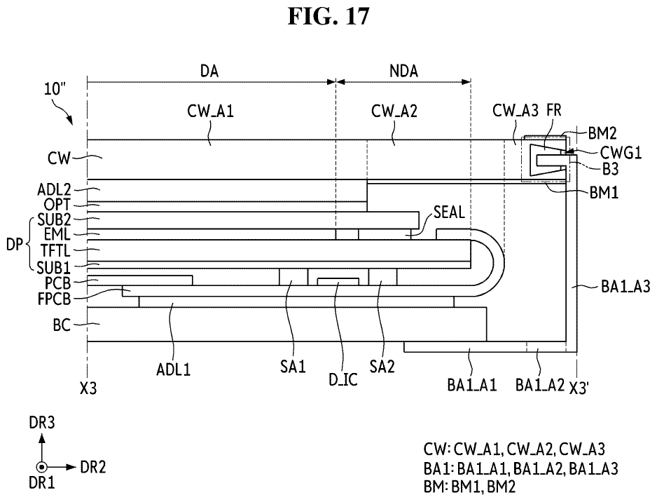

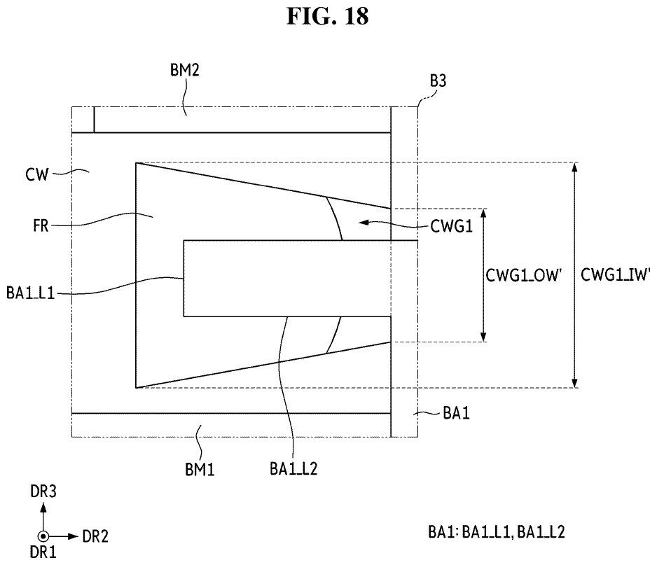

FIG. 16 is a bottom view of a display device 10″ according to still another embodiment. FIG. 17 is a cross-sectional view of the display device 10″ of FIG. 16 taken along line X3-X3′. FIG. 18 is an enlarged cross-sectional view of portion B3 of FIG. 17. Hereinafter, for convenience of description, the differences from embodiments described above will be mainly described and any repetitive detailed descriptions of the same or like elements as those described above will be omitted.

Referring to FIGS. 16, 17, and 18, in another embodiment, the third portion CW_A3 of the cover window may include a plurality of grooves CWG recessed inwardly from a side surface of the cover window CW. The third portion CW_A3 of the cover window may include a first groove CWG1 and a second groove CWG2 each positioned at an outer edge of the cover window CW in the first direction DR1. In such an embodiment, a width in the third direction DR3 of a boundary between the inner side of the cover window CW defining the first groove CWG1 and the outer side of the cover window CW is referred to as a third width CWG1_OW′ of the first groove, and a width in the third direction DR3 of a surface (or a innermost surface in the second direction DR2) opposite to the third width CWG1_OW′ of the first groove among the inner side surfaces of the cover window CW defining the first groove CWG1 is referred to as a fourth width CWG1_IW′ of the first groove. In some embodiments, the third width CWG1_OW′ of the first groove and the fourth width CWG1_IW′ of the first groove may be different from each other. In some embodiments, the third width CWG1_OW′ of the first groove may be smaller than the fourth width CWG1_IW′ of the first groove. Alternatively, in some embodiments, the third width CWG1_OW′ of the first groove may be greater than the fourth width CWG1_IW′ of the first groove. Alternatively, in some embodiments, the third width CWG1_OW′ of the first groove may be equal to the fourth width CWG1_IW′ of the first groove.

A first light blocking layer BM1 may be positioned on the surface of the cover window CW facing the display panel DP. The first light blocking layer BM1 may be positioned on the second portion CW_A2 and the third portion CW_A3 of the cover window. The first light blocking layer BM1 may effectively prevent the non-display area NDA of the display panel DP, the flexible printed circuit board (FPCB), and a portion of the first coupling structure BA1 overlapping the third portion CW_A3 from being visible to the user in the third direction DR3.

A second light blocking layer BM2 may be positioned on a surface of the cover window CW opposite to the surface of the cover window CW facing the display panel DP. The second light blocking layer BM2 may be positioned on the third portion CW_A3 of the cover window and may overlap the first groove CWG1 in the third direction DR3. The second light blocking layer BM2 may effectively prevent a portion of the first coupling structure BA1 coupled to the cover window CW from being visible to the user.

The first light blocking layer BM1 and the second light blocking layer BM2 may constitute or define a bezel of the display device 10.

A filler FR may be positioned between the surface of the third portion CW_A3 of the cover window CW facing the display panel DP and a surface of the cover window CW opposite to the surface facing the display panel DP. The filler FR may be positioned on the inner surface of the cover window CW defining the first groove CWG1 in the third portion CW_A3 of the cover window. The filler FR may fill the first groove CWG1 of the cover window CW defined in the third portion CW_A3 of the cover window. The filler FR may include a curable organic material. In some embodiments, the filler FR may include a heat or light curable resin.

The first coupling structure BA1 may include a first portion BA_A1 overlapping the bracket BC in the third direction DR3, a second portion BA1_A2 that does not overlap the bracket BC in the third direction DR3 and is positioned more externally (or outwardly) than the first portion BA1_A1, and a third portion BA1_A3 that does not overlap the display panel DP in the third direction DR3 and is positioned more externally than the second portion BA1_A2. The third portion BA1_A3 of the first coupling structure may be positioned around the flexible printed circuit board (FPCB), extend in a direction toward the cover window CW, and be further positioned in the groove CWG of the cover window CW. The third portion BA1_A3 of the first coupling structure may be in direct contact with the filler FR in the inner side of the cover window CW defining the first groove CWG1. The third portion BA1_A3 of the first coupling structure may be in direct contact with the filler FR in the inner side of the cover window CW defining the first groove CWG1, and a coupling force between the first coupling structure BA1 and the cover window CW may be formed by the filler FR. In such an embodiment, as the coupling force between the first coupling structure BA1 and the cover window CW is improved by the filler FR, the cover window CW and the bracket BC may be firmly coupled by the first coupling structure BA1. In such an embodiment, as the first coupling structure BA1 is coupled to the cover window CW, the first coupling structure BA1 may distribute the load applied from the cover window CW to the display panel DP. In such an embodiment, as the first coupling structure BA1 distributes the load applied from the cover window CW to the display panel DP, the load applied from the cover window CW to the display panel DP may be reduced, thereby reducing the risk of the sealing member SEAL of the display panel DP being peeled off. Therefore, reliability of the display device 10″ may be improved. In such an embodiment, since the cover window CW and the bracket BC are coupled by the coupling structure BA in the third portion CW_A3 of the cover window, the display device 10 may have a narrow bezel. Therefore, the display quality of the display device 10 may be improved.

Referring to FIG. 18, the first coupling structure BA1 may include a first surface BA1_L1 opposite to the boundary between the inner side of the cover window CW defining the first groove CWG1 and the outer side of the cover window, and a second surface BA1_L2 intersecting the first surface BA1_L1. The first surface BA1_L1 and the second surface BA1_L2 of the first coupling structure may not be in direct contact with the inner side surface of the cover window CW defining the first groove CWG1. In some embodiments, the first surface BA1_L1 of the first coupling structure may be in direct contact with the inner side surface of the cover window CW defining the first groove CWG1, and the second surface BA1_L2 of the first coupling structure may not be in direct contact with the inner side surface of the cover window CW defining the first groove CWG1. Alternatively, in some embodiments, the first surface BA1_L1 of the first coupling structure may not be in direct contact with the inner side surface of the cover window CW defining the first groove CWG1, and the second surface BA1_L2 of the first coupling structure may be in direct contact with the inner side surface of the cover window CW defining the first groove CWG1. Alternatively, in some embodiments, the first surface BA1_L1 and the second surface BA1_L2 of the first coupling structure may be in direct contact with the inner side surface of the cover window CW defining the first groove CWG1.

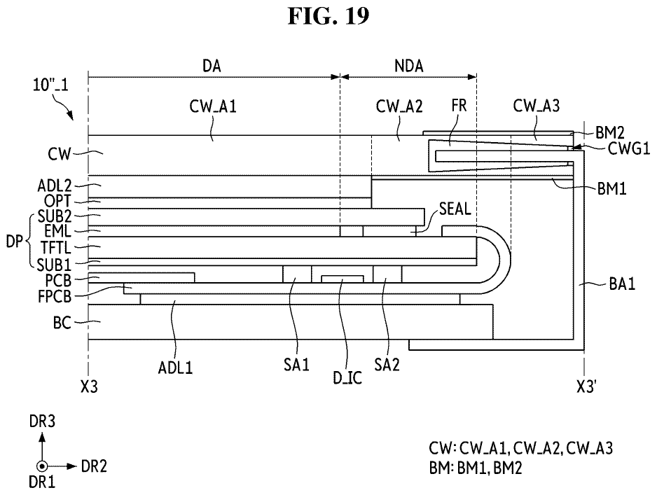

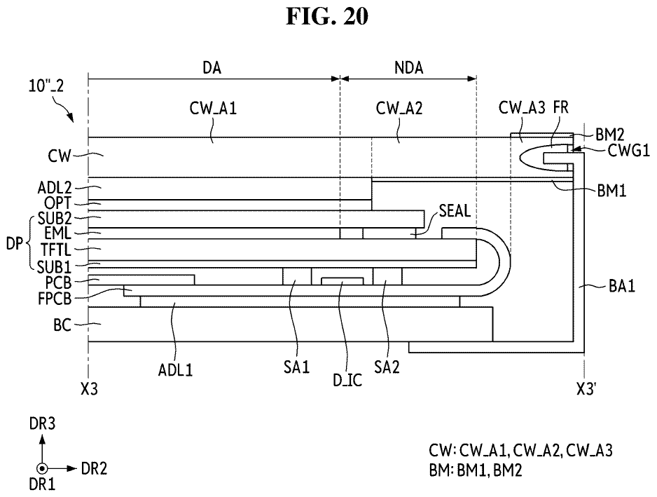

FIGS. 19 and 20 are cross-sectional views of display devices according to still other embodiments, showing a cross-section taken along line X3-X3′ of FIG. 16. Hereinafter, for convenience of description, the differences from embodiments described above will be mainly described and any repetitive detailed descriptions of the same or like elements as those described above will be omitted.

Referring to FIG. 19, in another embodiment, the first groove CWG1 positioned in the third portion CW_A3 of the cover window may further extend to the second portion CW_A2 of the cover window. In such an embodiment, as the first groove CWG1 positioned in the third portion CW_A3 of the cover window further extends to the second portion CW_A2 of the cover window, the first coupling structure BA1 positioned in the inner side of the cover window CW defining the first groove CWG1 may also extend further to the second portion CW_A2 of the cover window. In addition, the second light blocking layer BM2 may be further positioned on the second portion CW_A2 of the cover window to overlap the first groove CWG1 in the third direction DR3.

In such an embodiment, as the first groove CWG1 and the first coupling structure BA1 extend to the second portion CW_A2 in the third portion CW_A3 of the cover window, the coupling force between the first coupling structure BA1 and the cover window CW may be further improved. Therefore, the coupling force between the cover window CW and the bracket BC may be further improved by the first coupling structure BA1. In such an embodiment, as the surface area of the inner side surface of the cover window CW defining the groove CWG is increased, the pressure transmitted from the outside to the cover window CW may be reduced. In such an embodiment, as the surface area of the inner side surface of the cover window CW defining the first groove CWG1 is increased, a surface area of the filler FR filling the first groove CWG1 of the cover window CW is also increased, such that the coupling force between the cover window CW and the first coupling structure BA1 may be further improved by the filler FR. Therefore, the coupling force between the cover window CW and the bracket BC may be further improved by the first coupling structure BA1. Therefore, the reliability of the display device may be improved.

Referring to FIG. 20, in another embodiment, the inner side surface of the cover window CW defining the first groove CWG1 may include a curved surface. In such an embodiment, as the inner side surface of the cover window CW defining the first groove CWG1 includes the curved surface, a surface area of the inner side surface of the cover window CW defining the first groove CWG1 may be increased, so that pressure transmitted from the outside to the cover window CW may be reduced. In such an embodiment, as the surface area of the inner side surface of the cover window CW defining the first groove CWG1 is increased, a surface area of the filler FR filling the inner side of the cover window CW defining the first groove CWG1 is also increased, so that the coupling force between the cover window CW and the first coupling structure BA1 may be further improved by the filler FR. Therefore, the reliability of the display device 10 may be further improved. FIG. 20 illustrates an embodiment where the first groove CWG1 is positioned only in the third portion CS_A3 of the cover window, but not being limited thereto. In some embodiments, the first groove CWG1 may extend to the second portion CW_A2 of the cover window. In addition, the second blocking layer BM2 may be further positioned on the second portion CW_A2 of the cover window and may overlap the first groove CWG1 in the third direction DR3.

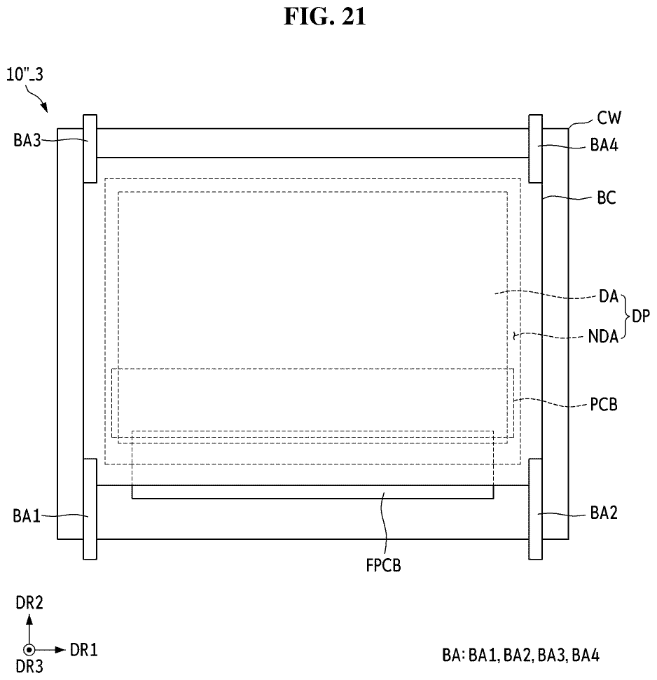

FIG. 21 is a bottom view of a display device according to still another embodiment.

Referring to FIG. 21, in another embodiment, the coupling structure BA may further include a third coupling structure BA3 and a fourth coupling structure BA4 disposed on the other sides opposite to one side on which the first coupling structure BA1 and the second coupling structure BA2 of the bracket BC are positioned. In such an embodiment, as the coupling structure BA of the display device further includes the third coupling structure BA3 and the fourth coupling structure BA4 disposed on the other sides opposite to one side on which the first coupling structure BA1 and the second coupling structure BA2 of the bracket BC are positioned, the coupling force between the cover window CW and the bracket BC may be further improved by the coupling structure BA. Therefore, the reliability of the display device may be further improved. In some embodiments, a plurality of coupling structures BA may be further disposed in the inner sides of the first coupling structure BA1 and the second coupling structure BA2, and the third coupling structure BA3 and the fourth coupling structure BA4.

The display device according to embodiments described above may be applied to various electronic devices. An electronic device according to an embodiment may include the display device described above, and may further include a module or device having additional functions in addition to the display device.

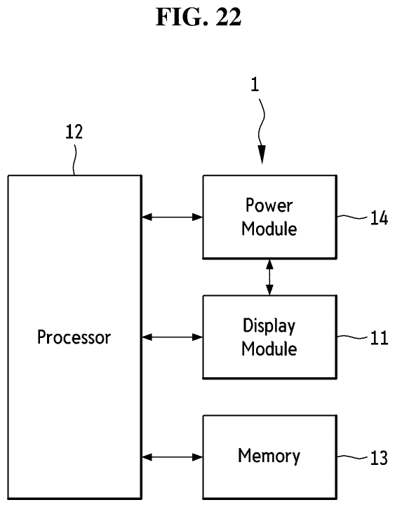

FIG. 22 is a block diagram of an electronic device according to an embodiment. Referring to FIG. 22, an electronic device 1 according to an embodiment may include a display module 11, a processor 12, a memory 13, and a power module 14.

The processor 12 may include at least one selected from a central processing unit (CPU), an application processor (AP), a graphic processing unit (GPU), a communication processor (CP), an image signal processor (ISP), and a controller.

Data information used for an operation of the processor 12 or the display module 11 may be stored in the memory 13. When the processor 12 executes an application stored in the memory 13, image data signals and/or input control signals may be transmitted to the display module 11, and the display module 11 may process the provided signals and output image information through a display screen.

The power module 14 may include a power supply module, such as a power adapter or a battery device, and a power conversion module that converts power supplied by the power supply module to generate power used for an operation of the electronic device 1.

At least one of the components of the electronic device 1 described above may be included in the display device according to the above-described embodiments. In addition, some of the individual modules functionally included within one module may be included within the display device, while others may be provided separately from the display device. In an embodiment, for example, the display device includes the display module 11, and the processor 12, the memory 13 and the power module 14 may be provided in the form of other devices within the electronic device 1 other than the display device.

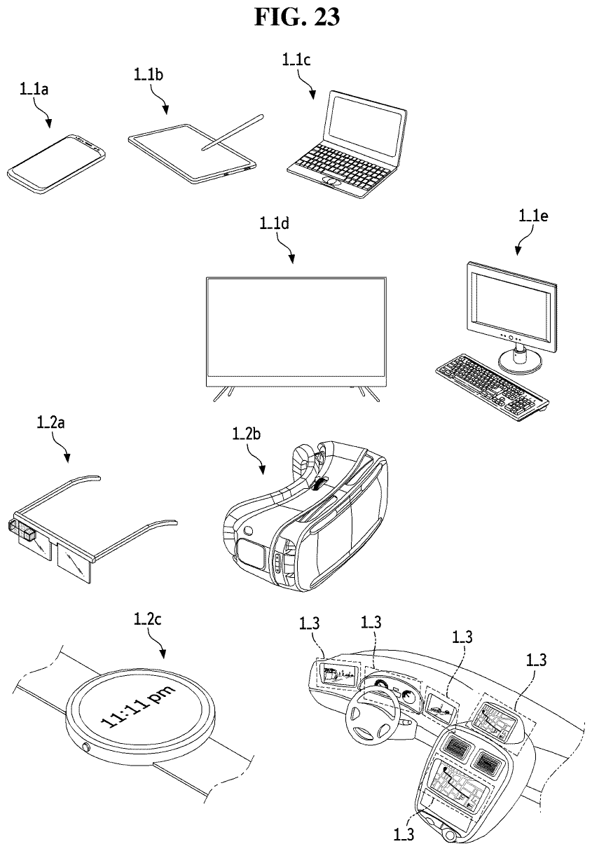

FIG. 23 illustrates schematic diagrams of electronic devices according to various embodiments.

Referring to FIG. 23, various electronic devices 1 to which the display device according to the embodiments is applied may include not only an image display electronic device such as a smart phone 1_1a, a tablet personal computer (PC) 1_1b, a laptop 1_1c, a television (TV) 1_1d, and a desk monitor 1_1e, but also a wearable electronic device including a display module such as a smart glasses 1_2a, a head mounted display 1_2b, a smart watch 1_2c, and the like, and a vehicle electronic device 1_3 including a display module such as a center information display (CID), a room mirror display, etc., disposed on a vehicle's instrument panel, center fascia, or dashboard.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel;
a flexible circuit board attached to the display panel and positioned outside the display panel;
an optical member positioned on an upper surface of the display panel;
a cover window including a first portion positioned on the optical member and overlapping the optical member, a second portion which does not overlap the optical member and is positioned outside the first portion, and a third portion which does not overlap the display panel and the flexible circuit board and is positioned outside the second portion;
a filler positioned on a surface of the third portion of the cover window facing the display panel;
a bracket positioned on a lower surface of the display panel and overlapping the display panel; and
a coupling structure positioned on a surface of the bracket opposite to another surface of the bracket facing the display panel and further positioned around the flexible circuit board,
wherein a groove recessed inwardly from a surface of the cover window facing the display panel is defined in the third portion of the cover window,
the filler is positioned on inner side surfaces of the cover window defining the groove, and
one end of the coupling structure is positioned in the groove of the cover window and is in direct contact with the filler.

2. The display device of claim 1, wherein a direction of the cover window toward the display panel is defined as a first direction, and a direction intersecting the first direction is defined as a second direction, and
a width in the second direction of a surface facing the display panel among the inner side surfaces of the cover window defining the groove and a width of a boundary between the inner side surfaces of the cover window defining the groove and an outer side surface of the cover window in the second direction are different from each other.

3. The display device of claim 2, wherein the width in the second direction of the surface facing the display panel among the inner side surfaces of the cover window defining the groove is greater than the width of the boundary between the inner side surfaces of the cover window defining the groove and the outer side surface of the cover window in the second direction.

4. The display device of claim 3, further comprising a light blocking layer positioned on surfaces of the second portion and the third portion of the cover window facing the display panel, and further positioned on the inner side surfaces of the cover window defining the groove,
wherein the light blocking layer is positioned between the cover window and the filler, and
the coupling structure is not in direct contact with the light blocking layer.

5. The display device of claim 4, wherein the filler overlaps the groove of the cover window and is further positioned outside the cover window.

6. The display device of claim 3, further comprising a light blocking layer positioned on surfaces of the second portion and the third portion of the cover window facing the display panel, and further positioned on the inner side surfaces of the cover window defining the groove,
wherein the light blocking layer is positioned between the cover window and the filler, and
the coupling structure is in direct contact with the light blocking layer.

7. The display device of claim 2, wherein a direction of the cover window toward the display panel is defined as a first direction, and a direction intersecting the first direction is defined as a second direction, and
a width in the second direction of a surface facing the display panel among the inner side surfaces of the cover window defining the groove and a width of a boundary between the inner side surfaces of the cover window defining the groove and an outer side surface of the cover window in the second direction are equal to each other.

8. The display device of claim 2, wherein the groove penetrates through the cover window, and
the display device further comprises a light blocking layer includes a first light blocking layer positioned on surfaces of the second portion and the third portion of the cover window facing the display panel, and a second light blocking layer positioned on a surface of the cover window opposite to the surfaces of the second portion and the third portion of the cover window facing the display panel and overlapping the groove of the cover window.

9. The display device of claim 2, wherein the bracket and the coupling structure are integrally formed as a single unitary indivisible part.

10. The display device of claim 2, wherein the coupling structure includes a first coupling structure and a second coupling structure positioned on one side of the bracket overlapping the flexible circuit board.

11. The display device of claim 10, wherein the coupling structure further includes a third coupling structure and a fourth coupling structure positioned on another side of the bracket opposite to the one side of the bracket.

12. The display device of claim 2, wherein the inner side surfaces of the cover window defining the groove includes a curved surface.

13. The display device of claim 12, further comprising a light blocking layer positioned on surfaces of the second portion and the third portion of the cover window facing the display panel, and further positioned on the inner side surfaces of the cover window defining the groove,
wherein the light blocking layer is positioned between the cover window and the filler, and
the coupling structure is not in direct contact with the light blocking layer.

14. A display device comprising:
a display panel;
a flexible circuit board attached to the display panel and positioned on the outside of the display panel;
an optical member positioned on an upper surface of the display panel;
a cover window including a first portion positioned on the optical member and overlapping the optical member, a second portion which does not overlap the optical member and is positioned outside the first portion, and a third portion which does not overlap the display panel and the flexible circuit board and is positioned outside the second portion;
a filler positioned between a surface of the cover window facing the display panel and another surface of the cover window opposite to the surface facing the display panel;
a bracket positioned on a lower surface of the display panel and overlapping the display panel; and
a coupling structure positioned on a surface of the bracket opposite to another surface of the bracket facing the display panel and further positioned around the flexible circuit board,
wherein a groove recessed inwardly from a side surface of the cover window is defined in the third portion of the cover window,
the filler is positioned on inner side surfaces of the cover window defining the groove, and
one end of the coupling structure is positioned in the groove of the cover window and is in direct contact with the filler.

15. The display device of claim 14, further comprising a light blocking layer includes a first light blocking layer positioned on surfaces of the second portion and the third portion of the cover window facing the display panel, and a second light blocking layer positioned on a surface opposite to the surfaces of the second portion and the third portion of the cover window facing the display panel and overlapping the groove of the cover window.

16. The display device of claim 15, wherein the coupling structure is not in direct contact with the cover window.

17. The display device of claim 15, wherein the groove extends to the second portion of the cover window.

18. The display device of claim 14, wherein the coupling structure includes a first coupling structure and a second coupling structure positioned on one side of the bracket overlapping the flexible circuit board.

19. The display device of claim 18, wherein the coupling structure further includes a third coupling structure and a fourth coupling structure positioned on another side of the bracket opposite to the one side of the bracket.

20. An electronic device comprising:
a display device for displaying an image; and
a processor for transmitting an image data signal for displaying the image to the display device,
wherein the display device comprises:
a display panel;
a flexible circuit board attached to the display panel and positioned on the outside of the display panel;
an optical member positioned on an upper surface of the display panel;
a cover window including a first portion positioned on the optical member and overlapping the optical member, a second portion which does not overlap the optical member and is positioned outside the first portion, and a third portion which does not overlap the display panel and the flexible circuit board and is positioned outside the second portion;
a filler positioned on a surface of the third portion of the cover window facing the display panel;
a bracket positioned on a lower surface of the display panel and overlapping the display panel; and
a coupling structure positioned on a surface of the bracket opposite to another surface of the bracket facing the display panel and further positioned around the flexible circuit board,
wherein a groove recessed inwardly from a surface of the cover window facing the display panel is defined in the third portion of the cover window,
the filler is positioned on inner side surfaces of the cover window defining the groove, and
one end of the coupling structure is positioned in the groove of the cover window and is in direct contact with the filler.
